(19) United States
(12) Patent Application Publication
(10) Pub. No.: US 2019/0280464 A1
(43) Pub. Date: Sep. 12, 2019

(54) IGNITION CONTROL SYSTEM FOR A HIGH-VOLTAGE BATTERY SYSTEM

(71) Applicant: SEMICONDUCTOR COMPONENTS INDUSTRIES, LLC, Phoenix, AZ (US)

(72) Inventor: Qingquan TANG, Breinigsville, PA (US)

(73) Assignee: SEMICONDUCTOR COMPONENTS INDUSTRIES, LLC, Phoenix, AZ (US)

(21) Appl. No.: 15/914,370

(22) Filed: Mar. 7, 2018

(51) Int. Cl. H01T 15/00; F02P 11/00; H03K 17/567

(52) U.S. Cl. CPC H01T 15/00; H01F 38/12; H03K 17/567; F02P 11/00

(57) ABSTRACT

In an implementation, a circuit can include a switch circuit configured to be electrically connected to an ignition circuit, a high-side path control circuit electrically connected between the switch circuit and a battery terminal, and a low-side path control circuit electrically connected between the switch circuit and a ground terminal. The circuit can include a control circuit configured to detect an abnormal condition associated with the ignition circuit where the control circuit can be configured to activate the high-side path control circuit in response to the detected abnormal condition.

### TECHNICAL FIELD

This description relates to an ignition circuit that can be used in a high-voltage battery system.

### BACKGROUND

Ignition systems can use a variety of high voltage devices such as insulated-gate bipolar transistor (IGBT) devices, ignition coils, and so forth. In some situations, failure of one or more components in an ignition system can cause catastrophic damage to elements of the system and/or a vehicle in which the system is implemented. For instance, a shorted IGBT device may overload a corresponding ignition coil. Such overloading of the ignition coil may result in irreparable damage to the ignition coil and could, in some instances, result in the ignition system causing an engine fire (e.g., due to the ignition coil combusting as a result of excessive current and associated heating in the ignition coil). The likelihood of failures and damage to ignition systems can be increased when using, for example, high-voltage batteries.

### SUMMARY

In an implementation, a circuit can include a switch circuit configured to be electrically connected to an ignition circuit, a high-side path control circuit electrically connected between the switch circuit and a battery terminal, and a low-side path control circuit electrically connected between the switch circuit and a ground terminal. The circuit can include a control circuit configured to detect an abnormal condition associated with the ignition circuit where the control circuit can be configured to activate the high-side path control circuit in response to the detected abnormal condition.

In another implementation, a circuit can include a switch circuit configured to be electrically connected to an ignition circuit, a high-side path control circuit electrically connected between the switch circuit and a battery terminal, and a low-side path control circuit electrically connected between the switch circuit and a ground terminal. The circuit can also include a control circuit configured to detect an over dwell-time condition associated with the ignition circuit where the control circuit is configured to deactivate the low-side path control circuit in response to the over dwell-time condition such that energy from the ignition circuit is dissipated via the switch circuit.

In yet another implementation, a circuit can include a switch circuit configured to be electrically connected to an ignition circuit, and a high-side path control circuit defining a looped path including the switch circuit, the battery terminal, and terminals configured to be electrically connected with the ignition circuit when the high-side path control circuit is activated. The circuit can include a low-side path control circuit defining a grounded path including the switch circuit, a first ignition circuit terminal, a second ignition circuit terminal, and a ground terminal, when the low-side path control circuit is activated. The first ignition circuit terminal and the second ignition circuit terminal can be configured to be electrically connected with ignition circuit. The circuit can include a control circuit configured to detect an over-current condition associated with the ignition circuit where the control circuit is configured to trigger oscillation between the looped path and the grounded path in response to the detected over-current condition.

### BRIEF DESCRIPTION OF THE DRAWINGS

FIG. 1 is a diagram that illustrates an ignition system including an ignition circuit, an engine control unit (ECU), and an ignition control circuit.

FIGS. 2A and 2B are diagrams that illustrate operation of the ignition control circuit shown in FIG. 1 during a soft shutdown (SSD) protection mode.

FIGS. 3A and 3B are diagrams that illustrate paths defined by the path control circuits described herein during a current-limit protection mode.

FIG. 4 is a block diagram that illustrates an example implementation of the ignition system illustrated in FIG. 1.

FIG. 5 is a diagram that illustrates an example implementation of the control circuit shown in FIGS. 1 and 4.

FIG. 6 is flowchart that illustrates a method of implementing a soft shutdown protection mode using an ignition control circuit.

FIG. 7 is flowchart that illustrates a method of implementing a current-limit protection mode using an ignition control circuit.

FIGS. 8A and 8B are diagrams that collectively illustrate current-limit protection operation of an ignition system.

FIGS. 9A and 9B are diagrams that collectively illustrate current-limit and soft-shutdown protection operation of an ignition system.

In the drawings, like elements are referenced with like reference numerals.

### DETAILED DESCRIPTION

An inductive discharge ignition system, such as the ignition systems described herein, can be used to ignite a fuel mixture in a cylinder of an internal combustion engine. Ignition systems may operate in relatively harsh environments and, therefore, can be subject to failure as a result of these operating conditions, as well as other factors that may cause system failure. These ignition systems can include devices configured to operate at relatively high voltages (e.g., 400 V or more) because the devices can be used as, for example, ignition coil drivers and as protection circuits for the ignition coil drivers. The ignition systems described herein can be configured to operate within and manage these harsh and high-voltage environments.

For example, the ignition systems described herein can be configured to dissipate substantial power, when the ignition systems are used to protect the ignition coil and ignition/battery system in response to an abnormal condition (which can also be referred to as an abnormal mode or failure mode). As a specific example, in response to detecting an abnormal condition, the ignition systems described herein can be configured to activate a protection mode (e.g., a protection strategy), which can include a current-limit protection mode or a soft shutdown protection mode. During a current-limit protection mode or a soft shutdown protection mode, significant levels of power can be managed by the ignition systems described herein.

The ignition systems described herein can include circuits configured to manage protection modes at low power in response to an abnormal condition. The low-power management of protection modes can be particularly advantageous because the ignition systems described herein can then be used in wide variety of applications with a wider range of operating conditions than known ignition systems. For example, the ignition systems described herein can be configured to manage power in ignition systems used in low-voltage or high-voltage battery applications. Without the low-power management modes described herein, the level of power dissipation during protection could be an issue in even relatively low-voltage battery systems (e.g., 14 V battery systems). The ignition systems described herein can be configured to manage power dissipation during activation of protection modes in even relatively high-voltage battery systems (e.g., 24 V battery systems, 36 V battery systems, 48 V battery systems). In addition, the ignition systems described herein can be configured to manage power dissipation during activation of protection modes in response to spikes in battery voltage (e.g., battery voltage spikes from 14 V to 24 V to 48 V) that occur during jump starts, load dump conditions, an/or so forth. Without the low-power management during protection modes, the power dissipation during protection in a relatively high-voltage battery systems application can be, for example, more than 2 times (e.g., 3 times, 5 times, 10 times) the power dissipation in a relatively low-voltage battery applications.

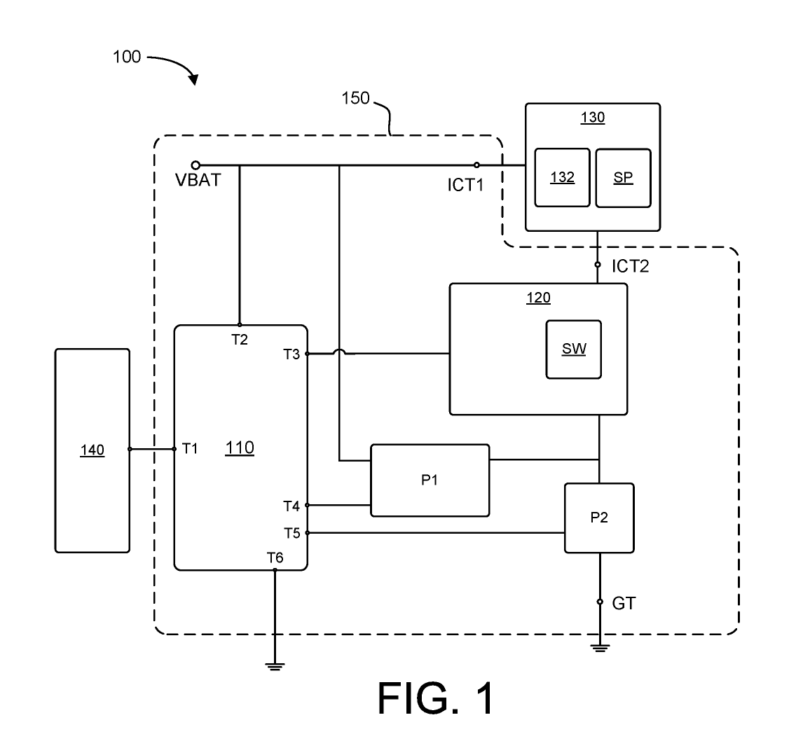

FIG. 1 is a diagram that illustrates an ignition system 100 including an ignition circuit 130, an engine control unit (ECU) 140, and an ignition control circuit 150. The ignition circuit 130 can include at least an ignition coil 132 and a spark plug SP. The ECU 140 can be configured to communicate with the ignition control system 150 to control charging of the ignition coil 132 within the ignition circuit 130. The ignition circuit 130 is electrically connected to the ignition control system 150 via ignition circuit terminals ICT1, ICT2.

As shown in FIG. 1, the ignition control system 150 includes a control circuit 110, a switch circuit 120, a high-side path control circuit P1, and a low-side path control circuit P2. The high-side path control circuit P1 and the low-side path control circuit P2 can be collectively referred to as path control circuits P. The switch circuit 120 includes a switch device SW, which can be electrically connected to the ignition circuit 130 (and ignition coil 132) via the ignition circuit terminal ICT2. The control circuit 110 is configured to interface with the ECU 140. The switch device SW can be, or can include, a transistor device (e.g., an insulated-gate bipolar transistor (IGBT), a metal-oxide-semiconductor field-effect transistor (MOSFET) device).

The path control circuits P are configured to control energy (e.g., current) along various paths within the ignition control system 150. In some implementations, the high-side path control circuit P1 and the low-side path control circuit P2 are configured to control the routing of energy from the ignition circuit 130 within the ignition control circuit 150.

As shown in FIG. 1, the high-side path control circuit P1 is electrically connected between a battery terminal VBAT and the switch circuit 120. In this implementation, the high-side path control circuit P1 is directly connected with the battery terminal VBAT. In other words, other circuit elements are not electrically connected (e.g., excluded) between the battery terminal VBAT and the high-side path control circuit P1. In this implementation, the high-side path control circuit P 1 is parallel to the ignition coil 132 and the switch device SW. The high-side path control circuit P1 is also electrically connected between a battery terminal VBAT and the low-side path control circuit P2. In this implementation, the high-side path control circuit P1 is directly connected with the low-side path control circuit P2. In other words, other circuit elements are not electrically connected (e.g., excluded) between the high-side path control circuit P1 and the low-side path control circuit P2. The low-side path control circuit P2 is electrically connected between the switch circuit 120 (and the switch device SW) and a ground terminal GT. The high-side path control circuit P1 and the low-side path control circuit P2 can be controlled by the control circuit 110.

The high-side path control circuit P1 can be referred as a high-side device because of the relative orientation of the high-side path control circuit P1 with respect to the low-side path control circuit P2. The high-side path control circuit P1 is coupled to a high side of the low-side path control circuit P2. The high-side path control circuit P1 can function as a complementary pair with the low-side path control circuit P2.

Activation of a circuit, such as the high-side path control circuit P1, the low-side path control circuit P2, and/or the switch device SW includes, for example, changing to an activation state or on-state, turning on or shorting across the circuit so that energy may flow across the circuit from one side of the circuit to the other side of the circuit. Deactivation of a circuit includes, for example, changing to a deactivation state or off-state, turning off or blocking by the circuit so that energy may not flow (e.g., may be limited) across the circuit from one side of the circuit to the other side of the circuit.

Under normal operation, the control circuit 110 is configured to trigger charging of the ignition coil 132 using a battery (e.g., a high-voltage battery at 48 V) coupled to the battery terminal VBAT by activating the low-side path control circuit P2 and the switch device SW. In some implementations, the low-side path control circuit P2 can be activated by the control circuit 110 before the switch device SW is activated by the control circuit 110.

When a spark is to be generated by the spark plug SP, the switch device SW can be rapidly turned off by the control circuit 110, while the low-side path control circuit P2 is maintained in an activated state by the control circuit 110. In some implementations, when a spark is to be generated by the spark plug SP, the switch device SW can be rapidly turned off by the control circuit 110, while the low-side path control circuit P2 is turned off with a delay time by the control circuit 110. During spark generation, the high-side path control circuit P2 can be controlled by the control circuit 110 to remain in a deactivated state. The ECU 140 can be configured to trigger the timing, via the control circuit 110, of generation of the spark.

In some implementations, the high-side path control circuit P1 and the low-side path control circuit P2 are configured to control (e.g., manage) energy from the ignition circuit 130 in response to detecting an abnormal condition (e.g., a failure). The high-side path control circuit P1 and the low-side path control circuit P2 can be controlled by the control circuit 110 to route energy from the ignition circuit 130 within the ignition control circuit 150 in response to an abnormal condition so that components within the ignition circuit 130 are protected. Specifically, the control circuit 110 can be configured to use the high-side path control circuit P1 and the low-side path control circuit P2 within a protection mode so that components (e.g., switch device SW) within the ignition system 100 are protected.

The control circuit 110 can be configured to control path control circuits P during different protection modes in response to detecting various types of abnormal conditions. The abnormal conditions can include, for example, a short-circuit condition (also can be referred to as a short failure), an over-current condition (can be referred to as a current-limit failure), an over dwell-time condition (can be referred to as a dwell-time failure), an over-voltage condition, an over-temperature condition, and/or so forth.

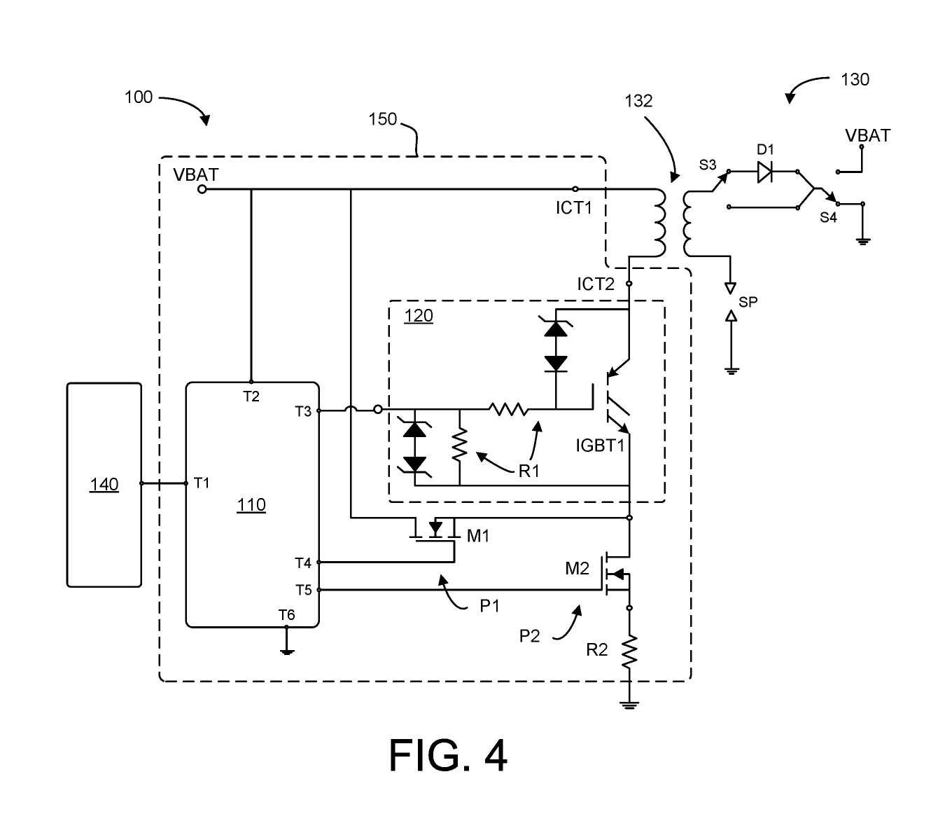

A short condition can occur, for example, when the ignition coil 132 and/or the switch device SW are shorted. An over-current condition can occur, for example, when a current (e.g., a primary current) through the ignition coil 132 exceeds a threshold current limit (e.g., 10 A, 15 A, 20 A). More details regarding the primary current are described in connection with at least FIG. 4. An over dwell-time condition can occur, for example, when a time period during which the ignition coil 132 is charged exceeds a threshold dwell time period (e.g., a maximum dwell time or dwell-time limit). The over dwell-time condition can be caused by, for example, a faulty ECU 140, a shorted command signal line to the control circuit 110 and/or battery coupled to the battery terminal VBAT (e.g., T1 or T3 shorted to VBAT), and/or so forth.

In some implementations, changes in primary current (e.g., bad ignition coil 132, over dwell-time condition, or high battery voltage transients) can indicate deterioration of components in such the ignition circuit 130, which can, result in a current that is above a desired current limit (overcurrent), or can indicate that energy is being dissipated unnecessarily in the ignition coil 132. Such overcurrents, or unnecessary (or undesirable) energy dissipation, can cause damage to the ignition coil 132 (e.g., the primary winding) and/or the switch device SW that is used as a switch to control charging and discharging of the ignition coil 132. Such damage or abnormal conditions (e.g., failure conditions) may cause the ignition system 100 to not function properly and/or could result in hazardous conditions, such as a fire. Accordingly, current-limit protection implemented by the ignition control circuit 150 can be critical.

In response to a short condition, the low-side path control circuit P2 can be deactivated by the control circuit 110 to protect the ignition system 100. In some implementations, in response to a short condition, the switch device SW and/or the high-side path control circuit P1 can be deactivated in addition to the low-side path control circuit P2. For example, in some implementations, in response to a short condition, both the high-side path control circuit P1 and the low-side path control circuit P2 can be deactivated to protect the ignition system 100. In some implementations, in response to a short condition, both the switch device SW and the low-side path control circuit P2 can be deactivated to protect the ignition system 100. In some implementations, in response to a short condition, the switch device SW, the high-side path control circuit P1, and the low-side path control circuit P2 can be deactivated to protect the ignition system 100. In such implementations, the low-side path control circuit P2 can function as a fuse (e.g., a solid-state fuse) for the ignition system 100 (and the ignition control circuit 150).

In response to an over dwell-time condition, a soft shutdown (SSD) protection mode can be activated by the control circuit 110. During the SSD protection mode, the low-side path control circuit P2 can be deactivated by the control circuit 110 and the switch device SW can be used to dissipate energy stored in the ignition coil 132. In some implementations, during the SSD protection mode, the switch device SW can be controlled in, for example, a linear mode to dissipate energy stored in the ignition coil 132. The level of energy dissipated during the SSD protection mode can be managed through the switch device SW in a desirable fashion by deactivating the low-side path control circuit P2 during dissipation of energy using the switch device SW. Accordingly, the switch device SW can be protected in a desirable fashion without damaging the switch device SW.

By controlling the switch device SW and/or the high-side path control circuit P1, power dissipation from the ignition coil 132 can be controlled by the control circuit 110 during the SSD protection mode. In some implementations, the control circuit 110 can regulate (e.g., control) current through the ignition coil 132. Specifically, the control circuit 110 can control power dissipation in a pre-defined profile. In some implementations, the control circuit 110 can regulate (e.g., control) a slew rate of the current through the ignition coil 132. In addition, the control circuit 110 can regulate (e.g., control) current through the ignition coil 132 independent of a voltage of a battery electrically connected to the battery terminal VBAT.

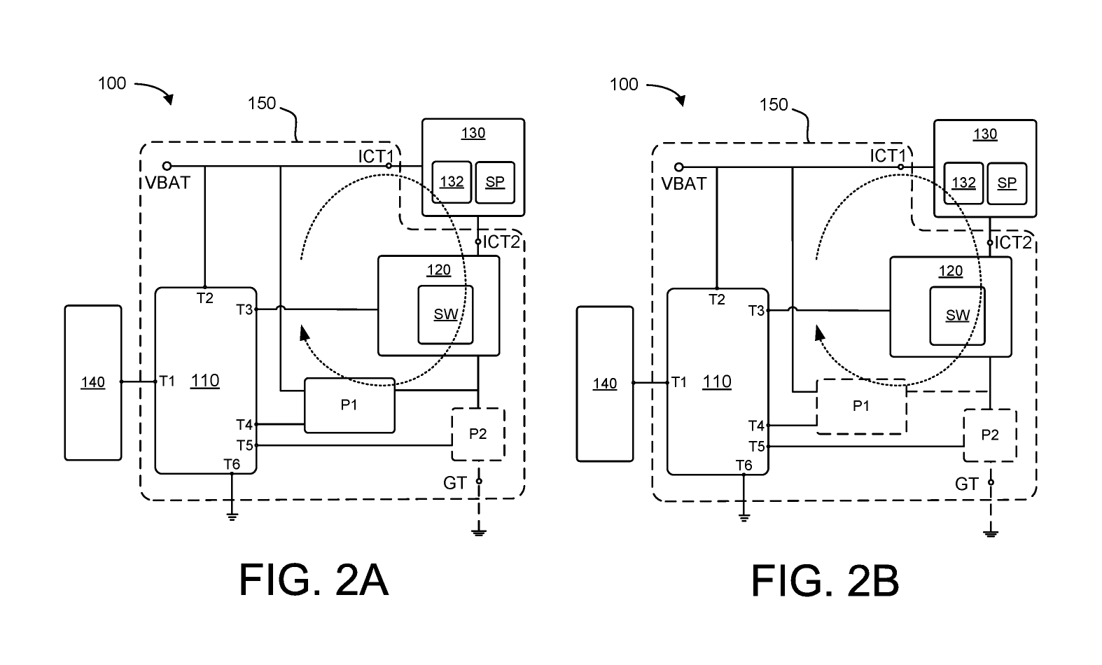

FIGS. 2A and 2B are diagrams that illustrate operation of the ignition control circuit 150 during a SSD protection mode. As shown in FIG. 2A, the low-side path control circuit P2 is deactivated (as represented by the dashed lines) and current I from the ignition coil 132 is dissipated across the switch device SW during the SSD protection mode. As shown in FIG. 2B, both the high-side path control circuit P1 and the low-side path control circuit P2 can be deactivated so that the current I is dissipated across (e.g., only across) the switch device SW during the SSD protection mode. A relatively small amount of energy (e.g., power, current), relative to energy (e.g., power, current) dissipated through the switch device SW, can be dissipated across the high-side path control circuit P1 as shown in both FIGS. 2A and 2B. In FIG. 2B, the energy (e.g., power, current) can be dissipated across, for example, a body diode included in the high-side path control circuit P1. In some implementations, the SSD protection mode can be implemented to prevent undesirable sparking.

Referring back to FIG. 1, in response to an over-current condition, a current-limit protection mode can be activated by the control circuit 110. During the current-limit protection mode, the control circuit 110 can be configured to switch (e.g., oscillate, alternate) between activation of the high-side path control circuit P1 and activation of the low-side path control circuit P2. The switching between activation of the high-side path control circuit P1 and activation of the low-side path control circuit P2 can be performed in an alternating fashion (e.g., in a complementary fashion). The switching can be performed to maintain a current through the ignition coil 132 at a specified current limit.

In some implementations, the current-limit protection described herein can prevent damage or hazardous conditions caused as a result of continuing to draw current through the primary winding of the ignition coil 132 (and an associated switch device SW) once the primary winding is fully charged (which can be referred to as charging saturation) and/or when the magnetic core of the ignition coil 132 has been magnetically saturated. The current-limit protection modes described herein also can protect the switch device SW.

In some implementations, the control circuit 110 can be configured to switch (e.g., alternately switch) between the high-side path control circuit P1 and the low-side path control circuit P2 at a specified frequency (e.g., at a frequency greater than 1 kHz (e.g., between 1 kHz and 20 kHz)) when in the current-limit protection mode. In other words, the control circuit 110 can be configured to trigger activation of the high-side path control circuit P1 and/or the low-side path control circuit P2 at a specified frequency (e.g., at a frequency greater than 1 kHz (e.g., between 10-20 kHz)) when in the current-limit protection mode. In some implementations, the frequency can be dynamically adjusted based on the current through the ignition coil 132. In some implementations, the frequency can be a pre-defined frequency.

In some implementations, the timing ratio (e.g., duty ratio) of activation/deactivation of the high-side path control circuit P1 and the low-side path control circuit P2 can be pre-defined based on the current through the ignition coil 132 (e.g., during current-limit protection mode). In some implementations, the timing ratio (e.g., duty ratio) of activation/deactivation of the high-side path control circuit P1 and the low-side path control circuit P2 can be dynamically (e.g., periodically) adjusted based on the current through the ignition coil 132 (e.g., during current-limit protection mode). In some implementations, the timing ratio (e.g., duty ratio) of activation/deactivation of the high-side path control circuit P1 and the low-side path control circuit P2 can be increased or decreased based on the current through the ignition coil 132. For example, a duration (e.g., time period) of activation of the high-side path control circuit P1 and the low-side path control circuit P2 can be longer than a duration of deactivation of the high-side path control circuit P1 and of the low-side path control circuit P2 based on the current through the ignition coil 132. As another example, a duration of activation of the high-side path control circuit P1 and the low-side path control circuit P2 can be shorter than a duration of deactivation of the high-side path control circuit P1 and of the low-side path control circuit P2 based on the current through the ignition coil 132.

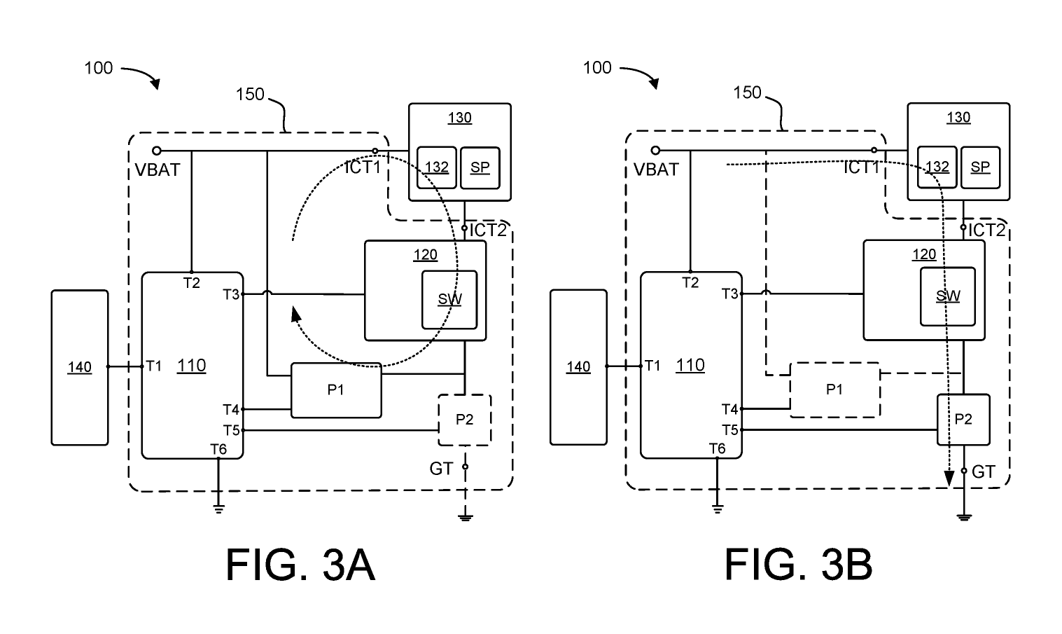

FIGS. 3A and 3B are diagrams that illustrate paths defined by the path control circuits P during a current-limit protection mode. Specifically, FIG. 3A illustrates a looped path (which can be referred to as a looped path configuration) and FIG. 3B illustrates a grounded path (which can be referred to as a grounded path configuration). The switching (e.g., alternating switching) described above can be between the looped path shown in FIG. 3A and the grounded path shown in FIG. 3B during current-limit protection mode.

When in the looped path configuration, the ignition coil 132 may be discharging (small conduction loss), and when in the grounded path configuration, the ignition coil 132 may be charging (e.g., charging via the battery electrically connected to the battery terminal VBAT). Thus, by switching between these path configurations, the current through the ignition coil 132 may be limited or maintained at a specified current limit. The current can be maintained about a current set point (or below a current limit) within a relatively tight range by switching between charging (grounded path) and discharging (looped path). The current can oscillate within a range about a current set point (or below a current limit) when switching between charging (grounded path) and discharging (looped path). In some implementations, some conduction loss may occur when switching between the looped path and the grounded path. Switching at a relatively high frequency (e.g., greater than 1 kHz) can help to maintain a tight range around a current limit set point.

As shown in FIG. 3A, the looped path (with direction of current illustrated by a dashed line) is defined when the high-side path control circuit P1 is activated and the low-side path control circuit P2 is deactivated (by the ignition control circuit 110). The looped path includes the battery terminal VBAT, the ignition circuit terminals ICT1, ICT2 (and the ignition circuit 130 and ignition coil 132), the switch circuit 120 (and switch device SW), and the high-side path control circuit P1. The looped path can include, in order, the battery terminal VBAT, the ignition circuit terminals ICT1, ICT2 (and the ignition circuit 130 and ignition coil 132), the switch circuit 120 (and switch device SW), and the high-side path control circuit P1. In the looped path configuration, the low-side path control circuit P2 is bypassed. The looped path also excludes the ground terminal GT. In some implementations, when in the looped path configuration, the switch device SW can be in a saturation mode or state.

As shown in FIG. 3B, the grounded path (with direction of current illustrated by a dashed line) defined when the high-side path control circuit P1 is deactivated and the low-side path control circuit P2 is activated (by the ignition control circuit 110). The grounded path includes the battery terminal VBAT, the ignition circuit terminals ICT1, ICT2 (and the ignition circuit 130 and ignition coil 132), the switch circuit 120 (and switch device SW), the low-side path control circuit P2, and the ground terminal GT. The grounded path can include, in order, the battery terminal VBAT, the ignition circuit terminals ICT1, ICT2 (and the ignition circuit 130 and ignition coil 132), the switch circuit 120 (and switch device SW), the low-side path control circuit P2, and the ground terminal GT. In the grounded path configuration, the high-side path control circuit P1 is bypassed. In some implementations, when in the grounded path configuration, the switch device SW can be in a saturation mode or state.

In some implementations, the switching between the grounded path configuration and the looped path can be performed with a symmetric timing (e.g., even timing). For example, alternating between the grounded path and the looped path can be performed with symmetric timing during cycles (e.g., same time period for grounded path and the looped path). In some implementations, the switching between the grounded path configuration and looped path can be performed with asymmetric timing (e.g., uneven timing). For example, alternating between the grounded path and the looped path can be performed with asymmetric timing during cycles (e.g., grounded path using for longer periods of time than the looped path). In some implementations, the symmetric or asymmetric handling of the switching between the grounded path and looped path can depend on the elements included in each of the paths (e.g., sizes of MOSFET devices, battery voltage, and/or ignition coil 132 primary inductance). In other words, in some implementations, the timing ratio (e.g., duty ratio) of activation/deactivation of the high-side path control circuit P1 and the low-side path control circuit P2 can be asymmetric. For example, a duration of activation of the high-side path control circuit P1 can be greater than a duration of activation of the low-side path control circuit P2 based on the current through the ignition coil 132. In such situations, the duration of deactivation of the high-side path control circuit P1 can be less than the duration of deactivation of the low-side path control circuit P2. As another example, a duration of activation of the high-side path control circuit P1 can be less than a duration of activation of the low-side path control circuit P2 based on the current through the ignition coil 132. In such situations, the duration of deactivation of the high-side path control circuit P1 can be greater than the duration of deactivation of the low-side path control circuit P2.

Referring back to FIG. 1, in some implementations, a spark in the spark plug SP can be triggered while the ignition control circuit 150 is implementing a current-limit protection mode. For example, if a dwell time expires (but does not exceed a dwell-time limit) while in the current-limit protection mode, the ignition control circuit 150 can trigger a spark using the switch device SW. In such implementations, the current-limit protection mode can be terminated when (e.g., before) the spark is triggered.

In some implementations, the control circuit can be configured to switch between the SSD protection mode and the current-limit protection mode (e.g., from the current-limit mode to SSD protection mode). For example, if during implementation of a current-limit protection mode a dwell-time limit is exceeded, the ignition control circuit 150 can be configured to implement (e.g., commence implementation of) a SSD protection mode.

FIG. 4 is a block diagram that illustrates an example implementation of the ignition system 100 illustrated in FIG. 1. As shown in FIG. 4, the ignition system 100 includes an implementation of the ignition circuit 130, the engine control unit (ECU) 140, and the ignition control circuit 150.

The switch circuit 120 includes as a switch device (e.g., switch device SW) an IGBT device IGBT1. Because the IGBT device IGBT1 can have a high input impedance, low conduction loss, relatively high switching speed, and/or robustness, the IGBT device IGBT1 can operate (e.g., integrate) well with the ECU 140 and integrated circuits (ICs), which are often implemented using complementary metal-oxide semiconductor processes. The switch circuit 120 also includes a resistor-diode network (network) R1. In some implementations, the resistor-diode network R1 can be excluded. The network R1, and specifically the Zener diodes between ICT2 and the IGBT device IGBT1 gate terminal, can be configured to define a high-voltage clamp for the ignition control circuit 150.

As shown in FIG. 4, the ignition circuit 130 includes an ignition coil 132 (e.g., a magnetic-core transformer) and a spark plug SP. In the implementation of FIG. 4, the ignition circuit 130 is illustrated with a high voltage diode D1 that is connected to a secondary winding of the ignition coil 132. The diode D1 can be used to suppress transient voltage spikes in the secondary winding of the ignition coil 132 at the beginning of a charging period (dwell time or dwell period) of the ignition coil 132. In some implementations, the diode D1 can be omitted and/or other transient suppression approaches can be used.

In this implementation, the high-side path control circuit P1 is a transistor device M1, and the low-side path control circuit P2 is a transistor device M2. Specifically, in this implementation, the high-side path control circuit P1 is an N-type MOSFET (NMOS) device M1, and the low-side path control circuit P2 is an NMOS device M2. In some implementations, the high-side path control circuit P1 can be, or can include, a diode.

In some implementations, the transistor device M1 and the transistor device M2 can be the same size (e.g., same width and/or same length). In some implementations, the transistor device M1 and the transistor device M2 can be different sizes (e.g., different width and/or different length).

As shown in FIG. 4, the control circuit 110 (e.g., control integrated circuit (IC)) includes a plurality of terminals. For example, the control IC 110 in this implementation includes terminals T1 through T6. These terminals T1 through T6 can each be a single terminal or can include respective multiple terminals, depending on the particular implementation and/or the particular terminal. For instance, in the control circuit 110, the terminal T1 can include multiple terminals that are coupled with an engine control unit (ECU) 140 to receive and/or send signals to the ECU 140. The ECU 140 may communicate a signal (or signals) to the circuit IC 110 via the terminal T1 (e.g., on a first terminal of the multiple terminals of terminal T1) that is used to control charging of the ignition coil 132 and firing of the spark plug SP (e.g. after charging the ignition coil 132 using energy stored in the ignition coil 132).

In an implementation, terminal T1 can be used to communicate one or more signals, from the ignition control circuit 150 to the ECU 140, that indicate occurrence of an abnormal condition, such as those discussed herein, and/or to indicate that the ignition control circuit 150 is operating normally or as expected. In some implementations, the terminal T1 could be a single bi-directional terminal configured to both send and receive signals, such as the signals described herein.

In FIG. 4, the terminal T2 of the control circuit 110 can be a power supply terminal that receives a battery voltage (V_{bat}) VBAT, such as from a battery (e.g., a battery of a vehicle) in which the ignition control circuit 150 is implemented. In the control circuit 110, the terminal T3 may be used to provide a signal that controls (e.g., drives, triggers) a gate of the IGBT device IGBT1 (e.g. to control charging of the ignition coil 132 and firing of the spark plug SP).

As shown in FIG. 4, a switch circuit S4 can be used to switch between the battery voltage VBAT and electrical ground. Likewise, a switch circuit S3 can be used to switch the diode D1 in and out of the charging/discharging circuit of the ignition coil 132 (e.g., to remove the diode from the charging/discharging circuit). The switch circuits S3 and S4 can be used to configure the charging/discharging circuit of the ignition circuit 130 for a particular implementation.

The terminals T4 and T5 can be terminals through which the high-side path control circuit P1 (e.g., NMOS device M1) and the low-side path control circuit P2 (e.g., NMOS device M2) are controlled (e.g., driven, triggered). The terminal T6 of the control circuit 110 can be a ground terminal that is connected with an electrical ground for the control circuit 110.

The ignition coil 132 has a primary coil electrically coupled to the ignition circuit terminals ICT1 and ICT2, and the ignition coil 132 has a secondary coil electrically coupled to the switch circuit S3 and the spark plug SP. In ignition circuit implementations, a ratio of a number of windings in the primary coil to a number of windings in the secondary coil can vary. For example, the number of windings in the primary coil can be less than the number of windings in the secondary coil (e.g., step-up). In still some implementations, the number of windings in the primary coil can be equal to (e.g., substantially equal to) the number of windings in the secondary coil.

A current in a primary winding (e.g., an inductor) of the ignition coil 132 (e.g., a magnetic core transformer), which can be referred to as a primary current, can be dependent on a variety of components and factors. In the ignition control circuit 150, changes in the primary current (as compared to the primary current expected during normal operation) can indicate improper operation of the ignition system 100. This improper operation can be caused by failure of one or more components in the ignition circuit 130, the ECU 140, the ignition control circuit 150, and/or so forth.

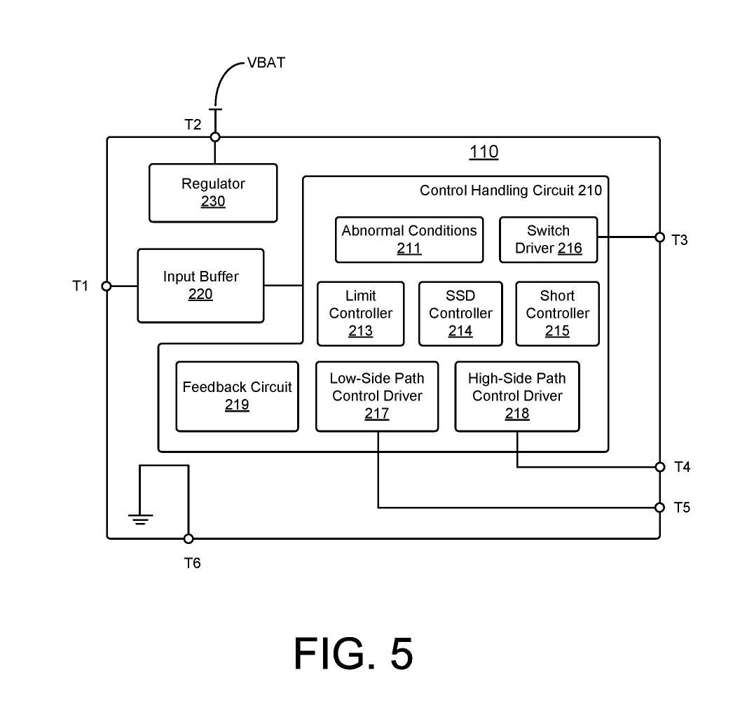

The ignition control circuit 150 of FIG. 4 also includes a resistor R2, which can be referred to as a sense resistor. The resistor R2 can be used, based on a time varying voltage across the resistor R2, to determine a current in the ignition coil 132 and also to detect changes in a slope of the primary current (e.g., to detect improper function and/or failures in the ignition system 100), such as the abnormal conditions discussed herein. Although not shown in FIG. 4, the control circuit 110 can be coupled to the resistor R2 (e.g., a terminal of the resistor R2) and can be configured to detect one or more of the abnormal conditions discussed herein. For example, a terminal (not shown) of the control circuit 110 can be configured to receive (or measure) a voltage, or voltage signal, across the resistor R2 of the ignition control circuit 150. The voltage across the resistor R2 over each ignition cycle, which can be referred to as a voltage sense signal, can be used for, for example, current slope detection for a current through a primary winding of the ignition coil 132. In some implementations, other circuit elements (in addition to the sense resistor R2 or instead of the sense resistor R2) can be used to determine the primary current through ignition coil 132. As noted above, in some implementations, current sensing through the primary winding of the ignition coil 132 can be used as feedback (e.g., as a feedback signal) to trigger switch (e.g., alternately switch) between the high-side path control circuit P1 and the low-side path control circuit P2 at a specified frequency and/or timing ratio (or duty ratio) of activation/deactivation (during various protection modes). More details regarding detection of abnormal conditions and protection modes are described in connection with at least FIG. 5.

FIG. 5 is a diagram that illustrates an example implementation of the control circuit 110 shown in FIGS. 1 and 4. As shown in FIG. 5, the control circuit 110 includes a control handling circuit 210, input buffer 220, and a regular 230.

The control handling circuit 210 includes a low-side path control driver 217 and a high-side path control driver 218 that are configured to, for example, control (e.g., drive, trigger), respectively, the low-side path control circuit P1 and the low-side path control circuit P2 shown in at least FIG. 1 (via the terminals T4 and T5). The control handling circuit 210 includes a switch driver 216 configured to, for example, drive the switch device SW shown in FIG. 1 (via terminal T3).

The control handling circuit 210 can be configured to detect one or more abnormal conditions (e.g., failure modes) such as an over-current condition, an over dwell-time condition, a short condition, an over-voltage condition, an over-temperature condition, and/or so forth. The control handling circuit 210 can be configured to detect one or more of these abnormal conditions based on one or more abnormal conditions 211. For example, the control handling circuit 210 can be configured to detect an over dwell-time condition based on a dwell-time threshold stored as or implemented by the abnormal conditions 211. In some implementations, the control handling circuit 210 can be configured to detect a failure using the resistor R2. In some implementations, one or more of the abnormal conditions 211 can be implemented at least in part as a hardware circuit.

The control handling circuit 210 includes a limit controller 213, an SSD controller 214, and a short controller 215. These controllers are configured to implement various protection modes by triggering control of, for example, the switch device SW, the high-side path control circuit P1, and/or the low-side path control circuit P2 using, respectively, the switch driver 216, the high-side path control driver 218, and/or the low-side path control driver 217. In some implementations, the control handling circuit 210 can include other controllers (not shown) that can be used to trigger control of the switch device SW, the high-side path control circuit P1, and/or the low-side path control circuit P2 in response to a variety of abnormal conditions.

In response to detection of a over-current condition using the control handling circuit 210, the limit controller 213 can be configured to implement a current-limit protection mode by, for example, triggering switching between the high-side path control circuit P1 and the low-side path control circuit P2 using, respectively, the low-side path control driver 217 and the high-side path control driver 218. In response to detection of an over dwell-time condition using the control handling circuit 210, the SSD controller 214 can be configured to implement an SSD protection mode by controlling, for example, the switch device SW, the high-side path control circuit P1, the low-side path control circuit P2 using, respectively, the switch driver 216, the high-side path control driver 218, and the low-side path control driver 217. In response to detection of a short failure using the control handling circuit 210, the short controller 215 can be configured to implement short protection mode by controlling, for example, the low-side path control circuit P2 using the low-side path control driver 217.

As shown in FIG. 5, the control handling circuit 210 includes a feedback circuit 219 configured to use a value (e.g., a representation) of energy (e.g., current) through the ignition coil 132 as feedback (e.g., as a feedback signal). The feedback can be used by the feedback circuit 219 to trigger switching (e.g., alternate switching) between the high-side path control circuit P1 and the low-side path control circuit P2 at a specified frequency and/or timing ratio (e.g., duty ratio) of activation/deactivation (during various protection modes).

The input buffer 220 of the ignition control circuit 110 in FIG. 5 can be configured to a receive at least one control signal from, for example, the ECU 140 shown in FIG. 4 (e.g., a signal to control charging of the ignition coil 132 and firing of the spark plug SP). The at least one control signal can be used in the ignition control circuit 110 to trigger control of a gate terminal of the IGBT device IGBT1 to effect charging of the ignition coil 132 and firing of the spark plug SP. The at least one control signal can be used, in some implementations, to facilitate detection of abnormal conditions and improper operation of the ignition control circuit 110.

The voltage regulator 230, when implemented in the ignition control circuit 110, can receive the battery voltage VBAT and, based on that battery voltage, provide reference voltages, direct-current voltages, etc. used in the ignition control circuit 110 of FIG. 4. For example, in some implementation, the regulator 230 can be a linear voltage regulator. In some implementations, the regulator 230 can take other forms.

In some implementations, in response to detecting an abnormal condition (e.g., a failure mode in the ignition coil 132 and/or magnetic saturation of the ignition coil 132) the control handling circuit 210 can be configured to send a signal to the ECU 140 to indicate the detected condition. In some implementations, the ECU 140 can be configured to adjust the command signal to control operation of the switch device SW, the high-side path control circuit P1, the low-side path control circuit P2 to protect the ignition system 100 from damage (e.g., prevent a dangerous condition, such as a fire from occurring).

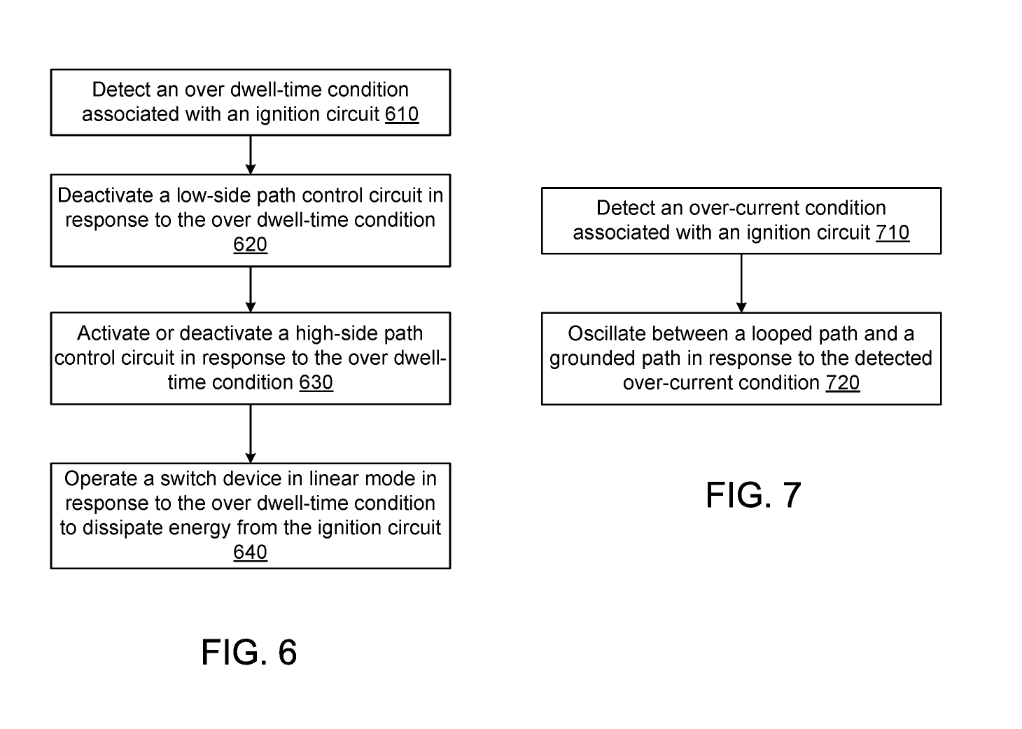

FIG. 6 is flowchart that illustrates a method of implementing a soft shutdown protection mode using an ignition control circuit (e.g., the ignition control circuit 150 shown in FIG. 1). As shown in FIG. 6, an over dwell-time condition associated with an ignition circuit is detected (block 610). The over dwell-time condition can occur when a dwell command pulse (to charge the ignition coil 132) from the ECU 140 exceeds a threshold dwell time period. The over dwell-time condition can be detected using, for example, the control handling circuit 210.

A low-side path control circuit is deactivated in response to the over dwell-time condition (block 620). The low-side path control circuit can be, for example, the low-side path control circuit P2 shown in FIG. 1. The low-side path control circuit can be, or can include, for example, a transistor (e.g., the MOSFET M1 shown in FIG. 4). The low-side path control circuit can be controlled by the control handling circuit 210 using the low-side path control driver 217 shown in FIG. 5.

A high-side path control circuit is activated or deactivated in response to the over dwell-time condition (block 630). The high-side path control circuit can be, for example, the high-side path control circuit P1 shown in FIG. 1. The high-side path control circuit can be, or can include, for example, a transistor (e.g., the MOSFET M1 shown in FIG. 4). The high-side path control circuit can be controlled by the control handling circuit 210 using the high-side path control driver 218 shown in FIG. 5.

A switch device is operated in linear mode in response to the over dwell-time condition to dissipate energy from the ignition circuit (block 640). The switch device can be, for example, the switch device SW shown in FIG. 1. The switch device can be, or can include, for example, a switch device (e.g., the IGBT device IGBT1 shown in FIG. 4). The switch device can be controlled by the control handling circuit 210 using the switch driver 216 shown in FIG. 5.

FIG. 7 is flowchart that illustrates a method of implementing a current-limit protection mode using an ignition control circuit (e.g., the ignition control circuit 150 shown in FIG. 1). As shown in FIG. 6, an over-current condition associated with an ignition circuit is detected (block 710). An over-current condition can occur, for example, when a current (e.g., a primary current) through the ignition coil 132 exceeds a threshold current limit (e.g., 10 A, 15 A, 20 A).

Oscillation between a looped path and a grounded path is performed in response to the detected over-current condition (block 720). An example looped path is shown in FIG. 3A and an example grounded path is shown in FIG. 3B.

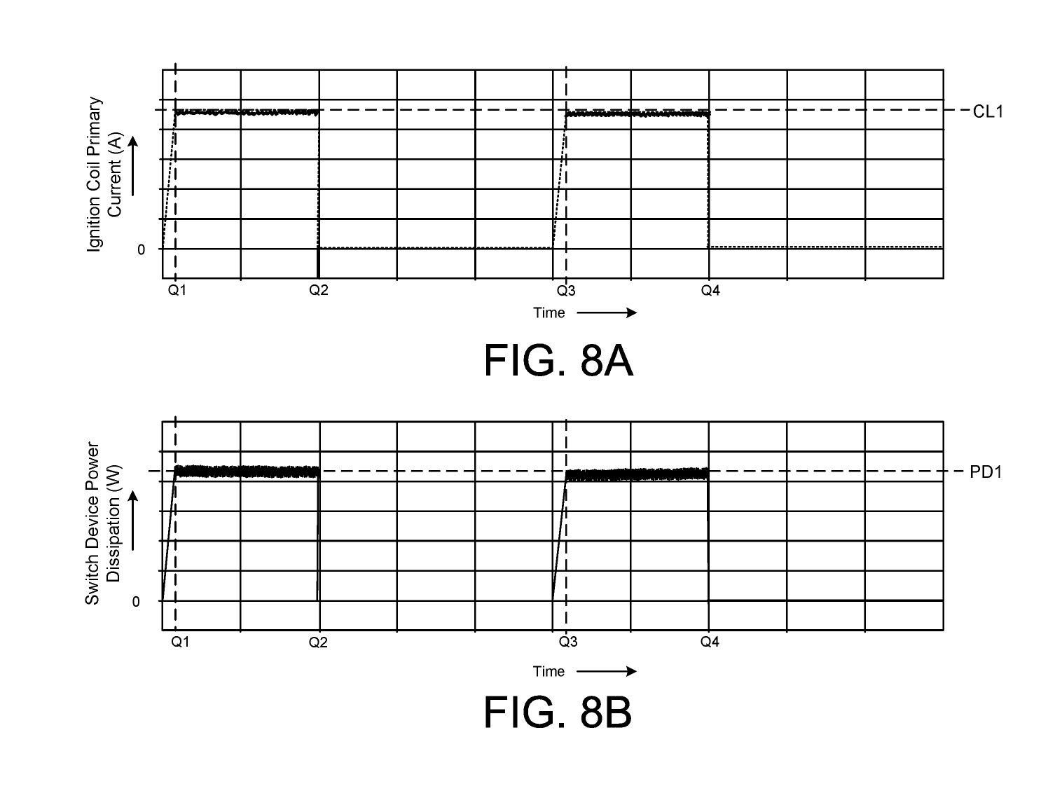

FIGS. 8A and 8B are diagrams that collectively illustrate current-limit protection operation of an ignition system (e.g., ignition system 100 shown in FIG. 1) using a high-battery voltage (e.g., 24V, 36 V, 48 V). In this example implementation, an ignition control circuit (e.g., ignition control circuit 150 shown in FIG. 1) implements a current-limit protection mode starting at times Q1 and Q3. The current-limit protection mode is implemented in this example during discrete periods of time (between time Q1-Q2 and Q3-Q4). FIG. 8A illustrates primary current through an ignition coil (e.g., ignition coil 132 shown in FIG. 1) versus time, and FIG. 8B illustrates switch device (e.g., switch device SW shown in FIG. 1) power versus time.

As shown in FIG. 8A, primary current through the ignition coil is limited below a current limit CL1. The current oscillates within a relatively narrow range below the current limit CL1 (e.g., a 12 A current limit) in response to switching between a high-side path control circuit and a low-side path control circuit (such as those shown in FIG. 1). During the current-limit protection mode, the power dissipated by the switch device is maintained at a desirable level around power level PD (e.g., less than 20 W (e.g., 16 W)). If the switch device is an IGBT device, for example, the Vce (collector-emitter voltage) of the IGBT device can be maintained below, for example, 2 V.

In some implementations, the current could be limited, during different times periods, to different current limits. For example, the current could be limited to a first current limit between times Q1 to Q2 and a second (and different (e.g., higher, lower)) current limit between times Q3 to Q4.

The table below illustrates a comparison of values from a known ignition control system (system B) and the ignition control system operation illustrated in FIGS. 8A and 8B (system A) assuming that the switch device is an IGBT device. As shown in table below, for the same current limit CL1, system A can have an IGBT device power that is 5 times lower and a Vce that is 4 times lower even with the battery voltage being 3.5 times higher. The Vce voltage can be particular high in the ignition control system B because the Vce of the IGBT device exceeds the battery voltage VBAT (e.g., during SSD protection mode) in order to dissipate power through the IGBT device. The Vce voltage can be particular high in the ignition control system B even during current-limit protection mode, and the Vce can increase with increasing battery voltage VBAT. Without the protection mode operation described herein, the ignition control system B, even though using a much lower battery voltage, can operate at current and voltage levels that could cause IGBT device failure. If using the higher battery voltage (e.g., 3.5 VBAT), the ignition control system B would operate at current and voltage levels that would be even higher and would cause IGBT device failure.

| | Ignition Control | Ignition Control |
|---|---|---|
| | System A | System B |
| Current Limit | CL1 | CL1 |
| VBAT | 3.5 × VBAT | VBAT |
| IGBT Device | PD | 5 × DP |
| Power | | |
| IGBT Vce | VCE | 4 × VCE |

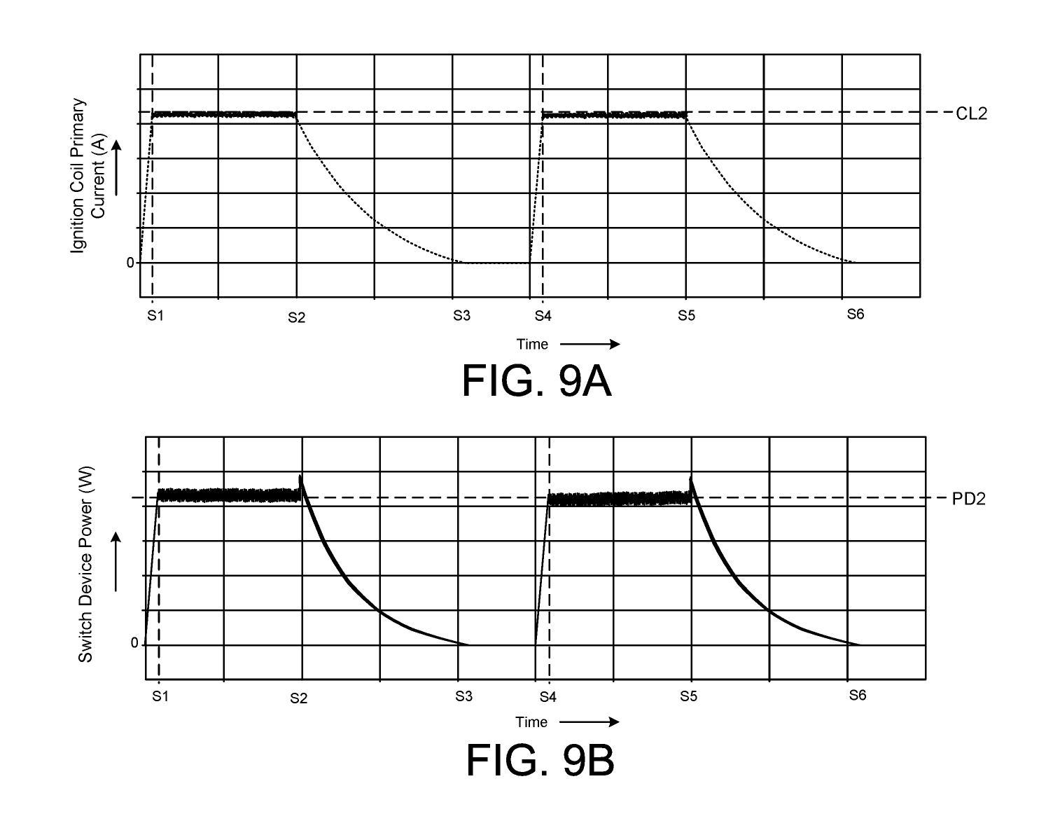

FIGS. 9A and 9B are diagrams that collectively illustrate current-limit and soft-shutdown protection operation of an ignition system (e.g., ignition system 100 shown in FIG. 1) using a high-battery voltage (e.g., 24V, 36 V, 48 V). In this example implementation, an ignition control circuit (e.g., ignition control circuit 150 shown in FIG. 1) implements a current-limit protection mode starting at times S1 and S4, and switches to a soft shutdown protection mode starting at times S2 and S5. FIG. 9A illustrates primary current through an ignition coil (e.g., ignition coil 132 shown in FIG. 1) versus time, and FIG. 9B illustrates switch device (e.g., switch device SW shown in FIG. 1) power versus time.

As shown in FIG. 9A, primary current through the ignition coil is limited below a current limit CL2 in the current-limit protection mode (similar to that shown and described in connection with FIGS. 8A and 8B) until switching to the soft shutdown protection mode. During the soft shutdown protection mode, the power of the switch device as shown in FIG. 9B is maintained at a desirable level around power level PD2 (e.g., less than 20 W (e.g., 16 W, 10 W)). The spike transient in switch device power at times and S2 and S5 is in response to switching between the current-limit protection mode and the soft shutdown protection mode. As shown in FIG. 9A, the ignition coil primary current is decreased (e.g., decreased in a non-linear fashion) between times S2 and S3 and between times S5 and S6 using the switch device. If the switch device is an IGBT device, for example, the Vce (collector-emitter voltage) of the IGBT device can be maintained below, for example, 2 V during the soft shutdown. In some implementations, more power can be dissipated by the IGBT device (by increasing Vce) to shorten the duration of the soft shutdown, which would increase the slope of the current decrease between times S2 and S3 and between times S5 and S6. In the power can be dissipated in a different profile (e.g., linear profile) by the IGBT device.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Implementations of the various techniques described herein may be implemented in (e.g., included in) digital electronic circuitry, or in computer hardware, firmware, software, or in combinations of them. Portions of methods also may be performed by, and an apparatus may be implemented as, special purpose logic circuitry, e.g., an FPGA (field programmable gate array) or an ASIC (application specific integrated circuit).

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A circuit, comprising:
a switch circuit configured to be electrically connected to an ignition circuit;
a high-side path control circuit electrically connected between the switch circuit and a battery terminal;
a low-side path control circuit electrically connected between the switch circuit and a ground terminal; and
a control circuit configured to detect an abnormal condition associated with the ignition circuit, the control circuit configured to activate the high-side path control circuit in response to the detected abnormal condition.

2. The circuit of claim 1, wherein the high-side path control circuit defines a looped path including the switch circuit, the battery terminal, and terminals configured to be electrically connected with the ignition circuit when the high-side path control circuit is activated and the low-side path control circuit is deactivated.

3. The circuit of claim 1, wherein the low-side path control circuit defines a grounded path including the switch circuit, the ground terminal, terminals configured to be electrically connected with ignition circuit when the low-side path control circuit is activated and the high-side path control circuit is deactivated.

4. The circuit of claim 1, wherein the abnormal condition is detected in response to at least one of a current limit through the ignition circuit being exceeded or a dwell-time limit being exceeded.

5. The circuit of claim 1, wherein the high-side path control circuit is activated as part of a soft shutdown protection mode.

6. The circuit of claim 1, wherein the high-side path control circuit is activated as part of a current limit protection mode.

7. The circuit of claim 1, wherein the control circuit is configured to trigger activation, at a frequency, the high-side path control circuit to limit current through the ignition circuit in response to the detected abnormal condition and based on feedback associated with a primary current through the ignition circuit.

8. The circuit of claim 1, wherein the control circuit is configured to trigger switching, at a pre-defined frequency, between the high-side path control circuit and the low-side control circuit to limit current in response to the detected abnormal condition.

9. The circuit of claim 1, wherein the control circuit is configured to trigger oscillating activation between the high-side path control circuit and the low-side path control circuit to limit current through the ignition circuit in response to the detected abnormal condition.

10. The circuit of claim 1, wherein the high-side path control circuit includes a first transistor, and the low-side path control circuit includes a second transistor.

11. The circuit of claim 1, wherein the ignition circuit includes an ignition coil and the switch circuit includes an insulated-gate bipolar transistor (IGBT) device.

12. A circuit, comprising:
a switch circuit configured to be electrically connected to an ignition circuit;
a high-side path control circuit electrically connected between the switch circuit and a battery terminal;
a low-side path control circuit electrically connected between the switch circuit and a ground terminal; and
a control circuit configured to detect an over dwell-time condition associated with the ignition circuit, the control circuit configured to deactivate the low-side path control circuit in response to the over dwell-time condition such that energy from the ignition circuit is dissipated via the switch circuit.

13. The circuit of claim 12, wherein the control circuit is configured to activate the high-side control circuit in response to the detection of the over dwell-time condition.

14. The circuit of claim 12, wherein the control circuit is configured to deactivate the high-side control circuit in response to the detection of the over dwell-time condition.

15. The circuit of claim 12, wherein the switch circuit includes an IGBT device, the IGBT device is operated in linear mode by the control circuit in response to the detection of the over dwell-time condition.

16. A circuit, comprising:
a switch circuit configured to be electrically connected to an ignition circuit;
a high-side path control circuit defining a looped path including the switch circuit, the battery terminal, and terminals configured to be electrically connected with the ignition circuit when the high-side path control circuit is activated;
a low-side path control circuit defining a grounded path including the switch circuit, a first ignition circuit terminal, a second ignition circuit terminal, and a ground terminal, when the low-side path control circuit is activated,
the first ignition circuit terminal and the second ignition circuit terminal configured to be electrically connected with ignition circuit; and
a control circuit configured to detect an over-current condition associated with the ignition circuit, the control circuit configured to trigger oscillation between the looped path and the grounded path in response to the detected over-current condition.

17. The circuit of claim 16, wherein the high-side path control circuit defines a looped path including the switch circuit, the battery terminal, and terminals configured to be electrically connected with the ignition circuit when the high-side path control circuit is activated and the low-side path control circuit is deactivated.

18. The circuit of claim 16, wherein the low-side path control circuit defines a grounded path including the switch circuit, the ground terminal, terminals configured to be electrically connected with ignition circuit when the low-side path control circuit is activated and the high-side path control circuit is deactivated.

19. The circuit of claim 16, wherein the low-side path control circuit is deactivated when the looped path is defined.

20. The circuit of claim 16, wherein the high-side path control circuit is deactivated when the ground path is defined.
